(19) United States
(12) Patent Application Publication
(10) Pub. No.: US 2023/0153666 A1
(43) Pub. Date: May 18, 2023

(54) SEMI-LOSSY PURCELL FILTER

(71) Applicant: INTERNATIONAL BUSINESS MACHINES CORPORATION, ARMONK, NY (US)

(72) Inventor: Joseph Robert Suttle, Chappaqua, NY (US)

(21) Appl. No.: 17/525,842

(22) Filed: Nov. 12, 2021

(51) Int. Cl. G06N 10/00; H01L 39/14

(52) U.S. Cl. CPC G06N 10/00; H01L 39/14

(57) ABSTRACT

A qubit system includes a qubit located on a first substrate. A readout resonator is coupled to the qubit and located on substrate having an attenuation constant the same as the first substrate. A first Purcell filter coupled to the readout resonator and located on a second substrate. The first substrate comprises a material that has an attenuation constant that is lower than that of the second substrate.

### BACKGROUND

### Technical Field

The present disclosure generally relates to superconducting devices, and more particularly, to qubit control that supports a scalable and modular quantum processor.

### Description of the Related Art

Superconducting quantum computing is an implementation of a quantum computer in superconducting electronic circuits. Quantum computation studies the application of quantum phenomena for information processing and communication. Various models of quantum computation exist, and the most popular models include the concepts of qubits and quantum gates. A qubit is a generalization of a bit that has two possible states, but can be in a quantum superposition of both states. A quantum gate is a generalization of a logic gate, however the quantum gate describes the transformation that one or more qubits will experience after the gate is applied on them, given their initial state. To increase the computational effectiveness and reliability of a quantum computer, the qubit count itself should be increased and the error rate reduced, which may be hampered by real estate limitations for a given environment, such as a cryogenic chamber. Various quantum phenomena, such as superposition and entanglement, do not have analogs in the world of classical computing and therefore may involve special structures, techniques, and materials.

### SUMMARY

According to one embodiment, a qubit system includes a qubit located on a first substrate, a readout resonator coupled to the qubit and located on a substrate having an attenuation constant that is the same as the first substrate, and a first Purcell filter, having a first pole, coupled to the readout resonator and located on a second substrate. The first substrate has an attenuation constant that is lower than that of the second substrate. In various embodiments, the qubit and the readout resonator can be on the same chip or on a separate chip.

In one embodiment, the qubit system of claim 1, further includes a second Purcell filter, having a second pole, coupled to an output of the first Purcell filter and located on the second substrate.

In one embodiment, a measurement and control module is coupled to an output of the first Purcell filter.

In one embodiment, the second substrate has an attenuation constant that is at least 100 times more than that of the first substrate.

In one embodiment, the attenuation constant of the first substrate is less than

$$1 {0}^{- 3} \frac{dB}{m} .$$

In one embodiment, the attenuation constant of the second substrate is greater or equal to

$$\text{.002} \frac{dB}{m}$$

and less than

$$1 \frac{dB}{m}$$

inclusive.

In one embodiment, a second Purcell filter is coupled between the readout resonator and the first Purcell filter. The second Purcell filter is on a substrate having an attenuation constant the same as the first substrate.

In one embodiment, the qubit, the readout resonator and the first Purcell filter are in a cryogenic environment.

In one embodiment, the second substrate is on a chip that is separate from that of the first substrate.

In one embodiment, the second substrate is on a printed circuit board (PCB) that is separate from that of the first substrate.

According to one embodiment, a method of interacting with a qubit includes providing a qubit on a first substrate. A readout resonator is coupled to the qubit. The readout resonator is provided on a substrate having an attenuation constant that is the same as the first substrate. A first Purcell filter, having a first pole, is coupled to the readout resonator. The first Purcell filter is provided on a second substrate. The first substrate has an attenuation constant that is lower than that of the second substrate.

In one embodiment, a second Purcell filter, having a second pole, is coupled to an output of the first Purcell filter. The second Purcell filter is provided on the second substrate.

In one embodiment, the second substrate has an attenuation constant that is at least 100 times more than that of the first substrate.

In one embodiment, the attenuation constant of the first substrate is less than

$$1 {0}^{- 3} \frac{dB}{m} .$$

In one embodiment, the attenuation constant of the second substrate is greater or equal to

$$. 002 \frac{dB}{m}$$

and less than

$$1 \frac{dB}{m}$$

inclusive.

In one embodiment, a second Purcell filter is coupled between the readout resonator and the first Purcell filter. The second Purcell filter is on the first substrate.

In one embodiment, the qubit, the readout resonator, and the first Purcell filter are housed in a cryogenic environment.

According to one embodiment, a qubit device includes a qubit located on a first substrate, a readout resonator coupled to the qubit and located on a substrate having an attenuation constant the same as the first substrate, a first Purcell filter, having a first pole, coupled to the readout resonator and located on a substrate having an attenuation constant the same as the first substrate, and a second Purcell filter coupled to an output of the first Purcell filter and located on a second substrate. The first substrate has an attenuation constant that is lower than that of the second substrate.

In one embodiment, the second substrate has an attenuation constant that is at least 100 times more than that of the first substrate.

In one embodiment, the attenuation constant of the first substrate is less than

$$1 {0}^{- 3} \frac{dB}{m} ,$$

and the attenuation constant of the second substrate is less than

$$1 \frac{dB}{m}$$

By virtue of the teachings herein higher readout speeds can be provided without significantly impacting coherence times. In one aspect, real estate on high quality substrates is reduced for a given architecture, thereby facilitating qubit scaling.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates an example architecture of a quantum computing system, consistent with an illustrative embodiment.

FIG. 2 is a conceptual block diagram of a qubit architecture that provides Purcell filtration, consistent with an illustrative embodiment.

FIG. 3 provides a conceptual block diagram of a qubit architecture that provides Purcell filtration on two separate substrates, consistent with an illustrative embodiment.

FIG. 4 is an example plot of a simulation result of the architecture of FIG. 2, consistent with an illustrative embodiment.

FIG. 5 provides an example plot of a simulation result of the architecture of FIG. 3, consistent with an illustrative embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In discussing the present technology, it may be helpful to describe various salient terms. As used herein a qubit represents a quantum bit and a quantum gate is an operation performed on a qubit, such as controlling the superposition of qubit states or entanglement of two qubits.

As used herein, a readout resonator is (e.g., very nearly) linear resonator that is connected to a qubit. The function of this resonator is two-fold: first, the center frequency of the resonator is dependent on the state of its qubit, which allows indirectly measuring the state of the qubit. Secondly, the resonator provides some amount of isolation between the qubit and the external environment, thus preventing the qubit's state from leaking out into the control/readout electronics.

A quantum processor (Q-processor) uses the unintuitive nature of entangled qubit devices (compactly referred to herein as “qubit,” or plural “qubits”) to perform computational tasks. In the particular realms where quantum mechanics operates, particles of matter can exist in multiple states—such as an “on” state, an “off” state, and both “on” and “off” states simultaneously. Where binary computing using semiconductor processors is limited to using just the ON and OFF states (equivalent to 1 and 0 in binary code), a quantum processor harnesses these quantum states of matter to output signals that are usable in data computing.

A driveline relates to a qubit control line that carries signals to the qubit. The term multiplexing includes the meaning of a single control line capable of carrying signals for multiple qubits. A stripline is a type of transmission line that may include a signal line embedded in dielectric with grounds above and below it. In many cases, there are also grounds in plane with the signal line. This structure is typically much more involved to fabricate but is very well isolated so that multiple striplines can be packed tightly together. In contrast, a coplanar waveguide (CPW) is a type of transmission line that may include three metal sheets, namely ground-signal-ground, which are all formed in a common plane (hence, coplanar). Such transmission lines typically only require a single metal level and are therefore simple to fabricate. However, CPWs have significant fringing fields, so they may need to be well separated to avoid crosstalk.

A Josephson junction (JJ) is a quantum mechanical device that is made of two superconducting electrodes separated by a barrier.

As used herein, certain terms are used indicating what may be considered an idealized behavior, such as “lossless,” “superconductor,” “superconducting,” “absolute zero,” which are intended to cover functionality that may not be exactly ideal but is within acceptable margins for a given application. For example, a certain level of loss or tolerance may be acceptable such that the resulting materials and structures may still be referred to by these “idealized” terms.

Although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

The present disclosure generally relates to superconducting devices, and more particularly, to more efficient architectures for Purcell filters. A Purcell filter is typically a bandpass or notch filter that blocks signal transmission in the qubit frequency band while passing signals in the readout resonator band. For example, the readout fidelity of superconducting transmon and Xmon qubits is partially limited by the qubit energy relaxation through the resonator into the transmission line, which is also known as the Purcell effect. One way to suppress this energy relaxation is to employ such a filter, which impedes microwave propagation at the qubit frequency. This filter can facilitate increasing the coupling from the readout resonator to external electronics (e.g., outside a cryogenic environment and typically at room temperature) while keeping the qubit isolated from them. Thus, the teachings herein can provide higher readout speeds without significantly impacting coherence times.

For example, the electromagnetic energy associated with a qubit can be stored in so-called Josephson junctions and in the capacitive and inductive elements that are used to form the qubit. In one example, to read out the qubit state, a microwave signal is applied to the microwave readout cavity that couples to the qubit at the cavity frequency. The transmitted (or reflected) microwave signal goes through multiple thermal isolation stages and low-noise amplifiers that are used to block or reduce the noise and improve the signal-to-noise ratio. Alternatively, or in addition, a microwave signal (e.g., pulse) can be used to entangle two or more qubits. Much of the process is performed in a cold environment (e.g., in a cryogenic chamber), where the amount of space is limited, while the microwave signal of a qubit may ultimately be measured at room temperature, discussed in more detail later.

The states of the qubits in a quantum computer can be described using wave functions, which are mathematical representations of the quantum state of the system. Coherence is present in a quantum computing system when a phase relation exists between the states of the quantum computer, such as a phase relation between the quantum wave functions that describes the qubit states. Quantum computers rely on coherence to operate. A loss of quantum coherence relates to a loss of information to the outside environment and is destructive to the computations being performed. Coherence can be maintained by isolation of the qubits in the quantum computer from outside noise, such as thermal interactions and electromagnetic interactions, cause the coherence of the system to degrade in a process called quantum decoherence. Thus, quantum decoherence can be interpreted as the loss of information from the quantum system into its surrounding environment.

In one aspect, the time that it takes for decoherence to occur is a measure of the viability of a quantum computing architecture. The longer a quantum computer can maintain coherence, the more feasible it is to perform useful computations with that quantum computer. Finding ways to delay decoherence is therefore salient in the realm of quantum computing.

The amplitude and/or phase of the returned/output microwave signal carries information about the qubit state, such as whether the qubit has dephased to the ground or excited state. The microwave signal carrying the quantum information about the qubit state is usually weak (e.g., on the order of a few microwave photons) and is vulnerable to cross-talk.

A qubit system may include one or more readout resonators coupled to the qubit. A readout resonator may be a transmission line with a finite length that includes a capacitive connection to an external feedline on one side and is either shorted to the ground on the other side, such as for a quarter wavelength resonator, or may have a capacitive connection to ground, such as for a half wavelength resonator, which results in oscillations within the transmission line, with the resonant frequency of the oscillations being detuned from the frequency of the qubit. For example, the qubit state affects a pulse coming from the control/measurement instruments at the readout resonator frequency and transmitted through or reflected off the readout resonator. The pulse acts as a measurement that decoheres the qubit and makes it collapse into a state of “one” or “zero,” thereby imparting a phase shift on that measurement pulse.

Transmission line resonators are typically quite large (e.g., around 5-10 mm long). In some cases, if the coupling between the readout resonator and its qubit is too large, it may be necessary to use a multi-pole Purcell filter to adequately isolate the qubit from the readout electronics. For example, the coupling between the readout resonator and its qubit may be too large when the coupling between the resonator and the qubit is large enough that the relaxation rate due to the Purcell effect through the readout is comparable to the relaxation rate due to internal loss of the qubit. In such a scenario, additional pole(s) may be added to the Purcell filter.

For an n-pole filter, the size of the Purcell Filter is approximately n times larger. In recent years, one or two poles may be sufficient. However, the inventor contemplates that, as coherence times improve, the number of poles may increase significantly.

Between qubits there may be a coupling resonator, sometimes referred to herein as a coupler resonator or RIP bus, which allows coupling different qubits together in order to realize quantum logic gates, sometimes referred to herein as entanglement. The coupling resonator is typically structurally similar to the readout resonator. However, more complex designs are possible. When a qubit is implemented as a transmon, each side of the coupling resonator is coupled (e.g., capacitively or inductively) to a corresponding qubit by being in adequate proximity to (e.g., the capacitor of) the qubit. Since each side of the coupling resonator has coupling with a respective different qubit, the two qubits are coupled together through the coupling resonator (e.g., RIP bus). In this way, there is mutual interdependence in the state between coupled qubits, thereby allowing to use the state of one qubit to control the state of another qubit. As used herein the term entanglement refers to when an interaction between two qubits is such that the states of the two cannot be specified independently, but can only be specified for the whole system. In this way, the states of two qubits are linked together such that a measurement of one of the qubits, causes the state of the other qubit to collapse into the joint state.

The ability to include more qubits is salient to being able to realize the potential of quantum computers. Generally, performance increases as temperature is lowered, for example by reducing the residual thermally-excited state qubit population and decreasing the thermal broadening of the qubit transition frequencies. Stated differently, the lower the temperature, the better for a quantum processor. Accordingly, some or all of the components discussed in the figures herein may be operated in a cryogenic environment.

To increase the computational power and reliability of a quantum computer, improvements can be made along two main dimensions. First, is the qubit count itself. The more qubits in a quantum processor, the more states can in principle be manipulated and stored. Second is low error rates, which is relevant to manipulate qubit states accurately and perform sequential operations that provide consistent results and not merely unreliable data. Thus, to improve fault tolerance of a quantum computer, a large number of physical qubits should be used to store a logical quantum bit. In this way, the local information is delocalized such that the quantum computer is less susceptible to local errors and the performance of measurements in the qubits' eigenbasis, similar to parity checks of classical computers, thereby advancing to a more fault tolerant quantum bit.

As mentioned above, one way to improve coherence times is by way of using a Purcell filter. For example, a qubit, or a multiplexed qubit array, may be coupled to a common Purcell filter. In one embodiment, the Purcell filter can be implemented as a transmission line resonator. This Purcell filter is configured to protect the qubit states from leaking out through the strongly coupled readout port.

In one aspect, the teachings herein are based on Applicants' insight that directly applying conventional integrated circuit techniques for interacting with computing elements to superconducting quantum circuits may not be effective because of the unique challenges presented by quantum circuits that are not presented in classical computing architectures. Accordingly, embodiments of the present disclosure are further based on recognition that issues unique to quantum circuits have been taken into consideration when evaluating applicability of conventional integrated circuit techniques to building superconducting quantum circuits, and, in particular, to electing methods and architectures used for interacting efficiently with qubits and providing a scalable and modular quantum processor architecture that can support thousands or millions of superconducting physical qubits.

The teachings herein provide structures that are resilient against quantum decoherence while providing a more efficient size, thereby facilitating qubit scaling. The techniques described herein may be implemented in a number of ways. Example implementations are provided below with reference to the following figures.

### Example Architecture

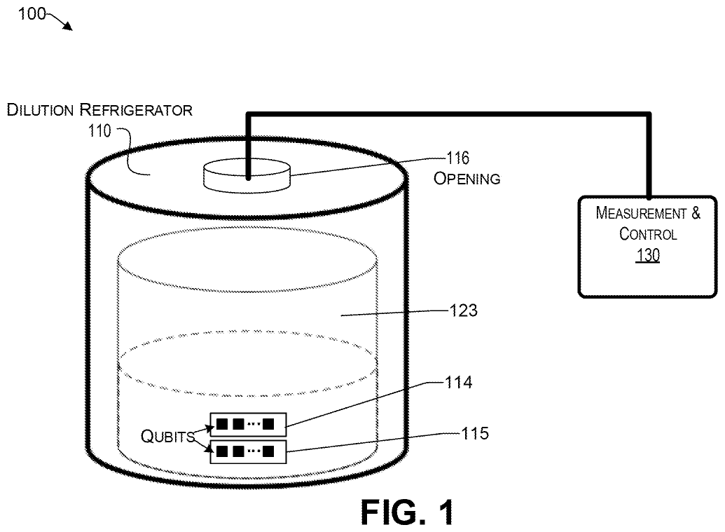

FIG. 1 illustrates an example architecture 100 of a quantum computing system, consistent with an illustrative embodiment. The architecture 100 includes a quantum processor 112 comprising one or more chips 114, 115. Each chip (e.g., 114, 115) includes a plurality of qubits. The quantum processor 112 is located in a refrigeration unit 110, which may be a dilution refrigerator. A dilution refrigerator is a cryogenic device that provides continuous cooling to temperatures typically 10 mK on its bottom temperature stage (that houses the quantum processor 112). Some support circuitry may located be at a higher temperature stage 123, which may be at 4K.

Most of the physical volume of the architecture 100 is due to the large size of the refrigeration unit 110. There is a measurement and control unit 130 that is outside of the refrigeration unit 110. The measurement and control unit 130 is able to communicate with the quantum processor through an opening 116, sometimes referred to as a bulkhead of the dilution refrigerator 110, that also forms a hermetic seal separating the ambient atmospheric pressure from the vacuum pressure of the cryostat under operation. A practical challenge in known refrigeration devices that house qubits chips 114 and/or 115 is that the number of qubits that can be accommodated in the refrigeration unit 110 is limited by various factors, including the number of wires between the measurement and control unit 130 and the qubits 114 measured/controlled thereby and the overall size of the qubits 114, 115, as well as its support circuitry.

Accordingly, in one aspect, what is provided herein is an architecture that can reduce the overall size of the qubits and corresponding circuitry, thereby facilitating qubit scaling.

### Example Block Diagrams

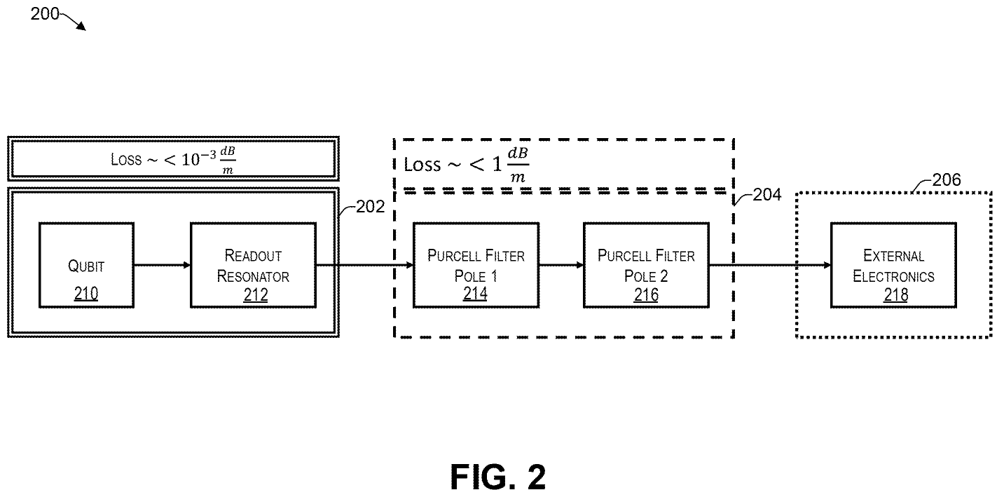

Reference now is made to FIG. 2, which is a conceptual block diagram of a qubit architecture 200 that provides Purcell filtration, consistent with an illustrative embodiment. Architecture 200 may have different types of substrates on which different components are constructed. As used herein, the term substrate refers to a foundation or level on which electronic components are built upon. In various embodiments, a substrate may relate to a planar wiring layer on a single crystal wafer or chip, a wiring layer in a multi-level wiring (MLW) stack which may be built on a single crystal wafer or chip, a wiring layer on a printed circuit board (PCB), a wiring layer on a laminate circuit board, a wiring layer in a flexible circuit assembly, or any other appropriate stage that can support the structures discussed herein. Each of these layers may be accessed by appropriate connectors, vias, and/or wiring.

Not all substrates may have a same level of quality (e.g., in terms of signal loss, which can be characterized by an attenuation constant for transmission lines built in that substrate). For example, some substrates may be used for more sensitive and/or high-performance components, whereas components that are not performance critical may be relegated to substrates that are of lower quality. In one embodiment, a high-quality substrate relates to one having an attenuation constant in the order of

$$1 {0}^{- 3} \frac{dB}{m} ,$$

or less. A lower quality substrate may relate to one having an attenuation constant that is greater or equal to

$$\text{.002} \frac{dB}{m} ,$$

such as an attenuation constant that is greater or equal to

$$. 01 \frac{dB}{m}$$

and even an attenuation constant that is greater or equal to

$$. 1 \frac{dB}{m} .$$

The lower quality substrate may be selected to have an attenuation constant less than or equal to

$$1 \frac{dB}{m} .$$

In some scenarios a ratio of the attenuation of a low quality substrate to a high quality substrate is greater than 10, and possibly greater than 100.

A simplistic approach may be to place all resonant structures on one or more high quality substrates. However, the reality is that these substrates may already be crowded. For example, transmission lines on these layers may be CPWs and therefore fairly wide (e.g., order of 10 μm) and have no isolation from one another, which may necessitate that they be kept well separated (e.g., order of 100 μm) to avoid spurious crosstalk. Accordingly, including the resonant structures discussed herein on these “high-quality” substrates prohibits being packed tightly without leading to cross-talk concerns. The architecture 200 of FIG. 2 removes such cross-talk concerns by separating one or more Purcell filters from the substrate of the qubit.

FIG. 2 provides a qubit system 200 that includes a qubit 210 located on a first substrate 202. There is a readout resonator 202 coupled to the qubit 210, which is also located on the first substrate. In one embodiment, the first substrate 202 has an attenuation constant that is

$$1 {0}^{- 3} \frac{dB}{m}$$

or less.

There is a first Purcell filter 214 coupled to the output of the readout resonator 202. The first Purcell filter is operative to provide a first pole. In some embodiments, a multi-pole Purcell filter can be used to adequately isolate the qubit 210 from the readout electronics. To that end, a second Purcell filter 216 may be coupled to the output of the first Purcell filter 214 to provide a second pole. While only two Purcell filters are depicted in FIG. 2, it will be understood that any number of poles may be implemented by cascading additional Purcell filters. Significantly, in the example embodiment of FIG. 2, the first and second Purcell filters 214, 216 are located on a separate (i.e., second) substrate 204. In one embodiment, the second substrate has a much more lenient loss (e.g., attenuation constant) that is

$$1 \frac{dB}{m}$$

or less. Accordingly, the first substrate 202 comprises a material that has an attenuation constant that is lower than that of the second substrate 204. The information from the qubit 210 can then be successfully read by way of external electronics 218. In one embodiment, the external electronics 218 are operated at room temperature 206, whereas the components on the first substrate 202 and the second substrate 204 are in a cryogenic environment. To facilitate the present discussion, the terms “first Purcell filter,” “second Purcell filter,” etc., are illustrated as separate filters. However, will be understood that they can be part of a same Purcell filter, each providing a separate pole. Stated differently, the terms “first Purcell filter” and “second Purcell filter” include the meaning of a Purcell filter having a first pole and a second pole.

Placing the one or more Purcell filters 214, 216 on separate substrates can substantially alleviate the density limitations on the number of qubits that can be placed on a common substrate without significantly affecting the integrity of the readout by the external electronics 218. This advancement is based on the inventor's insight that (i) a Purcell filter inherently has a low-quality factor Q, and (ii) a Purcell filter is isolated at least in part from the qubit 210 by the readout resonator 212. Accordingly, there is no substantive degradation in coherence for using one or more Purcell filters that are on a separate (e.g., 204) substrate. In some embodiments, the first and/or second Purcell filters 214, 216 can be implemented in stripline. This can further alleviate density limitations in that striplines can have finer features (e.g., widths of the order of 1 μm). Striplines can also be packed more tightly without unwanted crosstalk because their fringing fields are more tightly confined, especially when properly fenced in with vias.

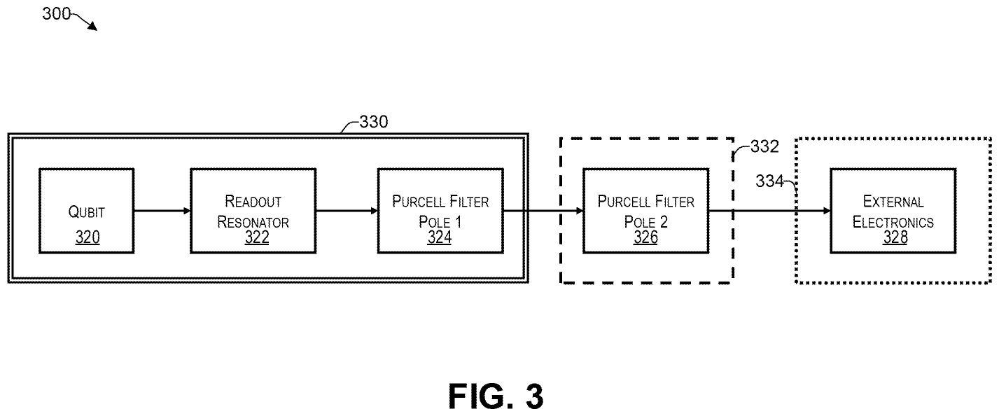

Even if a portion, and not the entirety, of the layout of the Purcell filter is located on a substrate that is separate from that of the qubit, substantial real estate can be saved. In this regard, FIG. 3 provides a conceptual block diagram of a qubit architecture 300 that provides Purcell filtration on two separate substrates, consistent with an illustrative embodiment. For example, the first substrate 330 has a higher level of quality than that of the second level 332.

In the example of FIG. 3, the first substrate 330 includes one or more qubits, represented by qubit block 320. There is a readout resonator 322 coupled to the output of the qubit 320. There is a first Purcell filter 324 having a first pole coupled to the output of the resonator 322.

The second substrate 332 includes a second Purcell filter, which provides the second pole 326. Additional poles may be provided at the output of the second Purcell filter 326 by simple concatenation (e.g., in series).

Similar to the architecture 200 of FIG. 2, placing at least some of the Purcell filters (e.g., 326) on a separate substrate can alleviate the density limitations on the number of qubits that can be placed on a common substrate without significantly affecting the integrity of the readout by the external electronics 328, which may be operated at room temperature 334 environment.

### Example Simulation Results

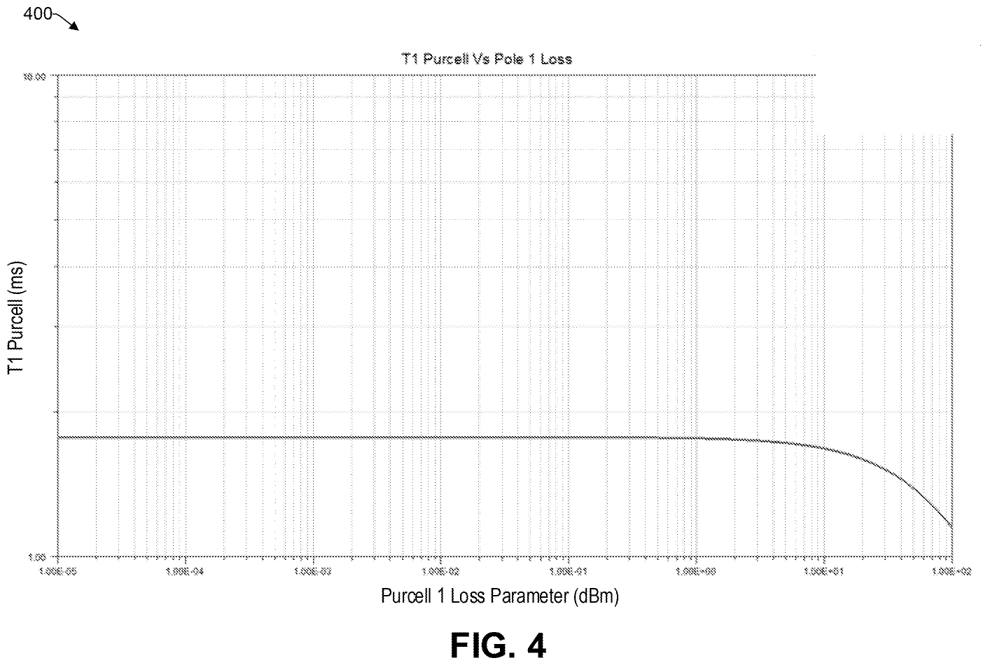

FIG. 4 is an example plot of a simulation result 400 of the architecture 200 of FIG. 2, consistent with an illustrative embodiment. More specifically, FIG. 4 illustrates a T1 Purcell versus first pole loss of Purcell filter 214. The simulation result 400 demonstrates that, when the attenuation constant of the first Purcell filter 214 of FIG. 2 is varied, that the relaxation time due to the Purcell effect is maintained relatively high at about 2 ms, and only begins to fall off at around

$$10 \frac{dB}{m} .$$

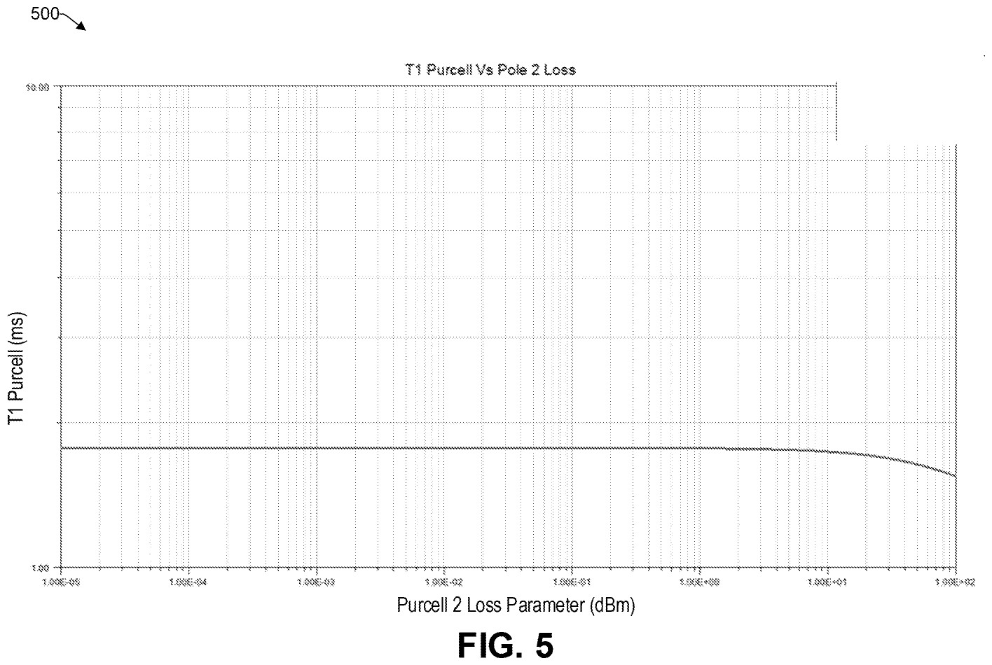

Similarly, FIG. 5 provides an example plot of a simulation result 500 of the architecture 300 of FIG. 3, consistent with an illustrative embodiment. The simulation result 500 demonstrates that, when the attenuation constant of the second Purcell filter 326 is varied, the relaxation time due to the Purcell effect is maintained relatively at about 2 ms and falls off after around

$$10 \frac{dB}{m}$$

(even higher than in result 400).

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

Aspects of the present disclosure are described herein with reference to a flowchart illustration and/or block diagram of a method, apparatus (systems), and computer program products according to embodiments of the present disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of an appropriately configured computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The call-flow, flowchart, and block diagrams in the figures herein illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A qubit system, comprising:
a qubit located on a first substrate;
a readout resonator coupled to the qubit and located on a substrate having an attenuation constant that is the same as an attenuation constant of the first substrate; and
a first Purcell filter having a first pole coupled to the readout resonator and located on a second substrate, wherein the attenuation constant of the first substrate is lower than that of the second substrate.

2. The qubit system of claim 1, further comprising a second Purcell filter having a second pole coupled to an output of the first Purcell filter and located on the second substrate.

3. The qubit system of claim 2, further comprising a measurement and control module coupled to an output of the first Purcell filter.

4. The qubit system of claim 1, wherein the attenuation constant of the second substrate is at least 100 times more than that of the first substrate.

5. The qubit system of claim 1, wherein the attenuation constant of the second substrate is greater or equal to
$$. 01 \frac{dB}{m} .$$

6. The qubit system of claim 1, wherein the attenuation constant of the second substrate is greater or equal to
$$. 1 \frac{dB}{m}$$

7. The qubit system of claim 1, further comprising a second Purcell filter, configured to provide an additional pole, coupled between the readout resonator and the first Purcell filter, wherein the second Purcell filter is on a substrate having an attenuation constant the same as the first substrate.

8. The qubit system of claim 1, wherein the qubit, the first Purcell filter is implemented in stripline.

9. The qubit system of claim 1, wherein the second substrate is on a chip that is separate from that of the first substrate.

10. The qubit system of claim 1, wherein the second substrate is on a printed circuit board (PCB) that is separate from that of the first substrate.

11. A method of interacting with a qubit, comprising:
providing a qubit on a first substrate;
coupling a readout resonator to the qubit and providing the readout resonator on a substrate having an attenuation constant that is the same as an attenuation constant of the first substrate; and
coupling a first Purcell filter having a first pole to the readout resonator and providing the first Purcell filter on a second substrate, wherein the attenuation constant of the first substrate is lower than that of the second substrate.

12. The method of claim 11, further comprising coupling a second Purcell filter, configured to provide a second pole, to an output of the first Purcell filter, and providing the second Purcell filter on the second substrate.

13. The method of claim 11, wherein the second substrate has an attenuation constant that is at least 100 times more than that of the first substrate.

14. The method of claim 13, wherein the attenuation constant of the first substrate is less than
$$1 {0}^{- 3} \frac{dB}{m} .$$

15. The method of claim 13, wherein the attenuation constant of the second substrate is greater or equal to
$$. 002 \frac{dB}{m}$$
and less than
$$1 \frac{dB}{m}$$
inclusive.

16. The method of claim 11, further comprising coupling a second Purcell filter between the readout resonator and the first Purcell filter, wherein the second Purcell filter is on a substrate having an attenuation constant the same as the first substrate.

17. The method of claim 11, further comprising housing the qubit, the readout resonator, and the first Purcell filter in a cryogenic environment.

18. A qubit device, comprising:
a qubit located on a first substrate;
a readout resonator coupled to the qubit and located on a substrate having an attenuation constant that is the same as the first substrate;
a first Purcell filter configured to provide a first pole coupled to the readout resonator and located on a substrate having an attenuation constant the same as the first substrate; and
a second Purcell filter coupled to an output of the first Purcell filter and located on a second substrate, wherein the first substrate has an attenuation constant that is lower than that of the second substrate.

19. The qubit device of claim 18, wherein the attenuation constant of the second substrate is at least 100 times more than that of the first substrate.

20. The qubit device of claim 19, wherein:
the attenuation constant of the first substrate is less than
$$1 {0}^{- 3} \frac{dB}{m} ;$$
and
the attenuation constant of the second substrate is greater or equal to
$$. 002 \frac{dB}{m}$$
and less than
$$1 \frac{dB}{m}$$
inclusive.
